(19) United States
(12) Patent Application Publication
(10) Pub. No.: US 2026/0146190 A1
(43) Pub. Date: May 28, 2026

(54) SLURRY COMPOSITION FOR CHEMICAL MECHANICAL POLISHING, POLISHING PAD FOR CHEMICAL MECHANICAL POLISHING, AND SEMICONDUCTOR DEVICE MANUFACTURING METHOD USING THE SAME

(71) Applicant: Samsung Electronics Co., Ltd., Suwon-si (KR)

(72) Inventors: Sanghuck Jeon, Suwon-si (KR); Junghun Kim, Suwon-si (KR); Seonghwa Bae, Suwon-si (KR); Youngkwan Seo, Suwon-si (KR); Hojin Jeong, Suwon-si (KR)

(21) Appl. No.: 19/273,801

(22) Filed: Jul. 18, 2025

(30) Foreign Application Priority Data
Nov. 25, 2024 (KR) 10-2024-0170062

(51) Int. Cl. C09K 3/14; B24B 37/04; B24B 37/24; C09G 1/02; H01L 21/321

(52) U.S. Cl. CPC C09K 3/1436; B24B 37/044; B24B 37/245; C09G 1/02; H10P 52/403

(57) ABSTRACT

A slurry composition including an abrasive particle is provided. The abrasive particle includes a core including a phase-change material that changes phase within a processing temperature range of a chemical mechanical polishing (CMP) process, and a shell including a material that is different from the phase-change material of the core and surrounding the core.

### CROSS-REFERENCE TO RELATED APPLICATION(S)

This application is based on and claims priority under 35 U.S.C. § 119 to Korean Patent Application No. 10-2024-0170062, filed on Nov. 25, 2024, in the Korean Intellectual Property Office, the disclosure of which is incorporated by reference herein in its entirety.

### BACKGROUND

In the semiconductor device manufacturing process, a CMP process is mainly used to polish the surface of a semiconductor device including a plurality of highly integrated components. As the integration of semiconductor devices increases, improving the reliability of the polishing process for manufacturing fine patterns becomes more important.

### SUMMARY

The present disclosure provides a slurry composition for chemical mechanical polishing (CMP) to easily control a process temperature, a polishing pad for CMP, and a semiconductor device manufacturing method using the same.

In addition, the present disclosure is not limited to the mentioned above. The other present disclosures not mentioned above may be easily understood by those skilled in the art from the following description.

According to an aspect of the present disclosure, a slurry composition includes an abrasive particle including a core including a phase-change material that changes phase within a processing temperature range of a CMP process, and a shell including a material that is different from that of the core and surrounding the core.

According to another aspect of the present disclosure, a polishing pad includes a base, and an abrasive particle disposed on a surface of the base and including a core including a phase-change material within a processing temperature range of a CMP process and a shell including a material that is different from that of the core and surrounding the core.

According to another aspect of the present disclosure, a semiconductor device manufacturing method includes forming an object to be polished on a substrate, and performing a chemical mechanical polishing (CMP) process using a slurry composition and a polishing pad to polish the object to be polished, wherein at least one of the slurry composition and the polishing pad includes an abrasive particle including a core including a phase-change material that changes phase in a temperature range of from about 30° C. to about 80° C. and a shell including a material that is different from that of the core and surrounding the core

### BRIEF DESCRIPTION OF THE DRAWINGS

Implementations will be more clearly understood from the following detailed description taken in conjunction with the accompanying drawings in which:

FIG. 1 is a partially-cut perspective view schematically showing some components of a polishing device, according to an implementation;

FIG. 2 is a cross-sectional view of an abrasive particle having a core-shell structure, according to an implementation;

FIG. 3 is a cross-sectional view of an abrasive particle having a core-shell structure, according to an implementation;

FIG. 4 is a plan view of an abrasive layer according to an implementation;

FIGS. 5A to 5M are cross-sectional views illustrating a semiconductor device manufacturing method, according to an implementation; and

FIGS. 6A to 6K are cross-sectional views illustrating a semiconductor device manufacturing method, according to an implementation.

### DETAILED DESCRIPTION

Implementations are described in detail with reference to the accompanying drawings. The same reference numerals are used for the same components in the drawings, and redundant description thereof is omitted.

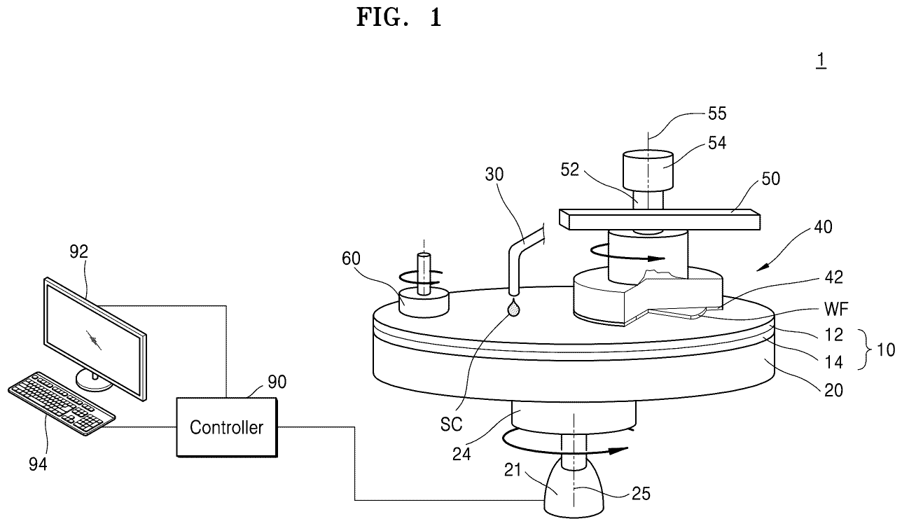

FIG. 1 is a partially-cut perspective view schematically showing some components of a polishing device, according to an implementation.

Referring to FIG. 1, a polishing device 1 may be used to polish a surface of a wafer WF in a chemical mechanical polishing (CMP) process. The polishing device 1 of FIG. 1 may rotate.

The polishing device 1 may include a platen 20 having a rotary disk shape. The platen 20 may be rotatably arranged about a central axis 25 of the platen 20 by using a motor 21. For example, the motor 21 may rotate a driving axis 24 to rotate the platen 20. A polishing pad 10 may be disposed on a top surface of the platen 20. The polishing pad 10 may include an abrasive layer 12 and a support layer 14. The support layer 14 may support the polishing pad 10 to be attached to the platen 20.

In an implementation, the polishing pad 10 may include a polishing pad having a three-dimensional structure. As the need for conditioning the polishing pad having a three-dimensional structure decreases, the sustainability of abrasive particles within the polishing pad 10 may increase.

For example, a film to be polished, such as a metal-containing film or an insulating film, may be formed on the wafer WF. The wafer WF may have a structure for forming an integrated circuit device, a structure for forming a thin film transistor-liquid crystal display (TFT-LCD), and a structure including various substrates, such as a glass substrate, a ceramic substrate, and a polymer substrate.

The polishing device 1 may include a slurry port 30 for supplying a slurry composition SC onto the polishing pad 10. The polishing device 1 may further include a polishing pad conditioner 60. The polishing pad conditioner 60 may be configured to perform a dressing process of periodically polishing and planarizing a surface of the polishing pad 10 so that the polishing pad 10 provides a certain polishing efficiency.

The polishing device 1 may include at least one carrier head 40. The carrier head 40 may be loaded with the wafer WF. With the wafer WF loaded on the carrier head 40 arranged to face the platen 20, the carrier head 40 may be configured to rotate while pressing the wafer WF toward the platen 20. Although only one carrier head 40 is shown on the polishing pad 10 in FIG. 1, a plurality of carrier heads 40 may be disposed on the polished pad 10. The carrier head 40 may be configured to control the pressure applied to the wafer WF.

The carrier head 40 may include a retaining ring 42 for holding the wafer WF. The carrier head 40 may be supported by a support structure 50, e.g., a carousel or a track, and may be connected to a carrier head rotation motor 54 through a driving axis 52 to rotate about a central axis 55 of the driving axis 52.

The polishing device 1 may further include a control system for controlling the rotation of the platen 20. The control system may include a controller 90, such as a general-purpose programmable digital computer, an output device 92, such as a monitor, and an input device 94, such as a keyboard. Although the control system is connected only to the motor 21 in FIG. 1, this is only an example. The control system may also be connected to the carrier head 40 to adjust the pressure or the rotational speed of the carrier head 40. In addition, the control system may be connected to the slurry port 30 to adjust the supply of the slurry composition SC.

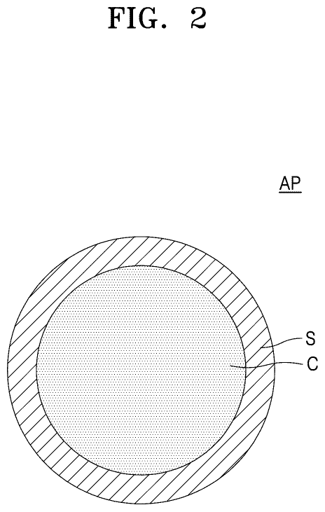

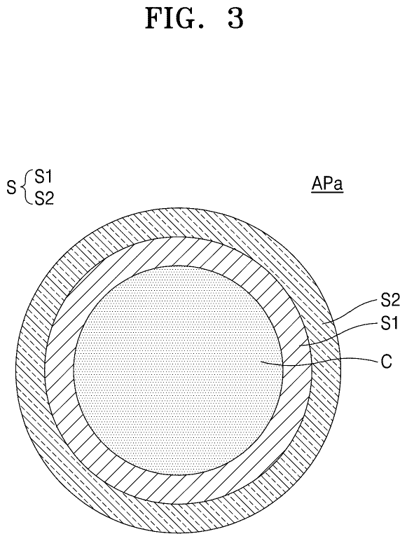

The slurry composition SC and/or the polishing pad 10 of the present disclosure may include a phase-change material that changes phase in a temperature range in which the CMP process is performed. The slurry composition SC and/or the polishing pad 10 of the present disclosure may include abrasive particles having a core-shell structure. The abrasive particles having a core-shell structure according to the present disclosure are described in detail below. The abrasive particles having a core-shell structure are described with reference to FIGS. 2 and 3.

### Abrasive Particles

FIG. 2 is a cross-sectional view of an abrasive particle having a core-shell structure, according to an implementation. FIG. 3 is a cross-sectional view of an abrasive particle having a core-shell structure, according to an implementation. FIG. 2 shows the abrasive particle including a shell of one layer and FIG. 3 shows the abrasive particle including shells of two layers.

Referring to FIGS. 2 and 3, abrasive particles AP and APa may have a core-shell structure. The core-shell structure may include a core C as a solid and a shell S surrounding the core C. The core C and the shell S may each include a different material. In an implementation, the abrasive particle having the core-shell structure may include shells S of one or more layers.

In an implementation, as shown in FIG. 2, the abrasive particle AP may include the core C and the shell S surrounding the core C.

In another implementation, as shown in FIG. 3, the abrasive particle APa may include a core C, a first shell S1 surrounding the core C, and a second shell S2 surrounding the first shell S1. The first shell S1 and the second shell S2 may form a structure of the shell S. Each of the core C, the first shell S1, and the second shell S2 may include a different material. In an implementation, the thermal conductivity of the first shell S1 may be greater than that of the second shell S2.

The core C may include a phase-change material. The core C may include a material that changes phase in a preset temperature range. In an implementation, the core C may include a material that changes phase at a processing temperature of the CMP process. In an implementation, the core C may include a material that changes phase between about 30° C. and about 80° C. In an implementation, the core C may include a material that changes phase between about 40° C. and about 70° C. In an implementation, the core C may include a material that changes phase between about 50° C. and about 60° C. In an implementation, the core C may include a fatty acid melted (or solidified) at about 30° C. to about 80° C. In an implementation, the core C may include a material melted (or solidified) at about 40° C. to about 70° C. In an implementation, the core C may include a material melted (or solidified) at about 50° C. to about 60° C. For example, the core may include lauric acid, palmitic acid, stearic acid, and/or myristic acid. However, the core is not limited thereto. The core C may include other types of materials.

The shell S may cover the core C. The shell S may include a material with high thermal conductivity. In an implementation, the shell S may include silica, alumina, ceria, titania, zirconia, magnesia, germania, and/or mangania, but not limited thereto. As described above, the shell S may include one or more layers.

In an implementation, the slurry composition SC and/or the polishing pad 10 may include abrasive particles AP and APa in an amount from about 0.05 wt. % to about 30 wt. %, based on the total weight of the slurry composition SC or the abrasive layer 12. In an implementation, the slurry composition SC and/or the polishing pad 10 may include abrasive particles in an amount from about 0.1 wt. % to about 20 wt. %, based on the total weight of the slurry composition SC and/or the abrasive layer 12. In an implementation, the slurry composition SC and/or the polishing pad 10 may include the abrasive particles in an amount from about 1 wt. % to about 10 wt. %, based on the total weight of the slurry composition SC and/or the abrasive layer 12. In an implementation, the slurry composition SC and/or polishing pad 10 may include the abrasive particles in an amount from about 2 wt. % to about 8 wt. %, based on the total weight of the slurry composition SC and/or the abrasive layer 12.

In an implementation, the abrasive particles AP and APa may have a size of about 5 nm to about 200 nm. In an implementation, the abrasive particles AP and APa may have a size of about 1 nm to about 10 nm. In an implementation, the abrasive particles AP and APa may have a size of about 10 nm to about 5 μm. In an implementation, the abrasive particles AP and APa may have a size of about 5 nm to about 10 μm.

The processing temperature may increase as the CMP process progresses. The occurrence of dishing, corrosion, wafer recess and/or pad elongation may increase when the processing temperature increases excessively. The dishing may refer to excessive polishing of the film material to be polished, and the corrosion may refer to chemical corrosion of the film material to be polished. The wafer recess may refer to excessively removing the wafer WF, and the pad elongation may refer to physically deforming the pad.

When the abrasive particles AP and APa include a phase-change material, the phase-change material may change phase when the processing temperature increases during the CMP process. When the phase-change material causes an endothermic reaction while changing phase, the increase in the processing temperature may be suppressed. The occurrence of dishing, corrosion, wafer recess and/or pad elongation described above may be reduced. In addition, as the processing temperature is controlled, the removal rate of the film material to be polished may be controlled.

Referring back to FIG. 1, the components constituting the slurry composition SC and the polishing pad 10 may be further described. In an implementation, the slurry composition SC may be used for polishing a metal material film. In another implementation, the slurry composition SC may be used for polishing an insulating material film. For example, the slurry composition SC may selectively include the aforementioned abrasive particles, a polishing accelerator, a pH adjuster, an oxidizing agent, water, a corrosion inhibitor, a catalyst, and/or a biocide. For example, the slurry composition SC may selectively include a surfactant, a polishing inhibitor, and/or a leveling agent.

### Polishing Accelerator

The slurry composition SC may further include the polishing accelerator to improve the polishing rate (or removal rate). The polishing accelerator may include an anionic low molecule, an anionic high molecule, a hydroxyl acid, or an amino acid. For example, the anionic low molecule may include at least one of a citric acid, a polyacrylic acid, a polymethacrylic acid, and a copolymeric acid or a salt thereof. In addition, the hydroxyl acid may include at least one of a hydroxybenzoic acid, an ascorbic acid, or a salt thereof. The non-limiting examples of the amino acid may include picolinic acid, serine, proline, arginine, asparagine, an aspartic acid, cysteine, glutamine, glutamic acid, glycine, histidine, lysine, phenylalanine, tyrosine, valine, tryptophan, betaine, pyroglutamic acid, amino butyric acid, pyridine carboxylic acid, polyethylene glycol amino ether acetic acid, and isoleucine.

The additional examples of the polishing accelerator may include quinone compound, such as 3-hydroxy-4-methyl-phenol anion or 3-hydroxy-4-hydroxymethyl-phenol anion, 4-methyl-benzene-1,3-diol, kojic acid, maltol propionate, and maltol isobutyrate. The non-limiting examples of the quinone compound may include at least one selected from the group including a dienone, a diol, and a dienol (dienol anion) including alkylbenzene diols and hydroxy and alkyl groups; a dienone, a diol, and a dienol (dienol anion) including a phenol anion and an alkyl group linked by oxo; and a dienone, a diol, and a dienol (dienol anion) including hydroxyalkyl and benzene rings.

Specifically, the non-limiting examples of the quinone compound include 4-alkyl-benzene-1,3-diol, 3-hydroxy-4-alkyl-cyclohexa-2,5-dienone, 6-alkyl-3-oxo-cyclohexa-1,4-dienol anion, 3-hydroxy-6-alkyl-cyclohexa-2,4-dienone, 4-alkyl-3-oxo-cyclohexa-1,5-dienol anion, 3-hydroxy-4-alkyl-phenol anion, 5-hydroxy-2-alkyl-phenol anion, 3-hydroxy-4-alkyl-phenol anion, 5-hydroxy-2-hydroxyalkyl-phenol anion, 3-hydroxy-4-hydroxyalkyl-phenol anion, 3-hydroxy-4-hydroxyalkyl-cyclohexa-2,5-dienone, 6-hydroxyalkyl-3-oxo-cyclohexa-1,4-dienol anion, 3-hydroxy-6-hydroxyalkyl-cyclohexa-2,4-dienone, 4-hydroxyalkyl-3-oxo-cyclohexa-1,5-dienol anion, and 4-hydroxyalkyl-benzene-1,3-diol.

The additional examples of the polishing accelerator may include ammonium hydrogen phosphate, ammonium dihydrogen phosphate, bis(2-ethylhexyl)phosphate, 2-aminoethyl dihydrogen phosphate, 4-chlorobenzenediazonium hexafluorophosphate, nitrobenzenediazonium hexafluorophosphate, ammonium hexafluorophosphate, bis(2,4-dichlorophenyl) chlorophosphite, bis(2-ethylhexyl) hydrogenphosphate, bis(2-ethylhexyl)phosphite, calcium fluorophosphate, diethyl chlorophosphate, diethyl chlorothiophosphate, potassium hexafluorophosphate, pyrophosphoric acid, tetrabutylammonium hexafluorophosphate, and tetraethylammonium hexafluorophosphate.

### pH Adjuster

The slurry composition SC may further include the pH adjuster for adjusting the pH of the composition. In an implementation, the slurry composition SC may have a pH of about 1 to about 9. In an implementation, the slurry composition SC may have a pH of about 2 to about 7. In an implementation, the slurry composition SC may have a pH of about 4 to about 9.

An acid solution and an alkali solution may be appropriately used to control the pH of the slurry composition SC. In an implementation, as the pH adjuster, the acid solution, such as sulfuric acid, phosphoric acid, hydrochloric acid, nitric acid, carboxylic acid, maleic acid, malonic acid, citric acid, oxalic acid, or tartaric acid and/or the alkali solution, such as calcium hydroxide, potassium hydroxide, ammonium hydroxide, sodium hydroxide, magnesium hydroxide, triethylamine, tetramethylammonium hydroxide, or ammonia, may be used, but is not limited thereto. The pH adjuster may be included in the slurry composition SC in an amount to allow the pH of the slurry composition SC to have a desired range and is not limited thereto.

### Oxidizing Agent

Generally, the slurry composition SC used for polishing the metal material film includes an oxidizing agent. The non-limiting examples of the oxidizing agent may include organic peroxides, such as peracetic acid, perbenzoic acid, and tert-butyl hydroperoxide; permanganic acid compounds, such as potassium permanganate; dichromic acid compounds, such as potassium dichromate; halogen acid compounds, such as potassium iodate; nitric acid compounds, such as nitric acid, and iron nitrate; perhalogen acid compounds, such as perchloric acid; persulfates, such as sodium persulfate, potassium persulfate, and ammonium persulfate; percarbonates, such as sodium percarbonate and potassium percarbonate; urea peroxides; and heteropoly acids.

### Water

The water contained in the slurry composition SC may include purified water. The content of the water in the slurry composition SC is not particularly limited thereto. The water may be included as the remainder in the slurry composition SC along with main components including the pH adjuster and/or the oxidizing agent.

### Corrosion Inhibitor

The slurry composition SC may further include the corrosion inhibitor consisting of an azole-containing compound or a water-soluble polymer including an anionic carboxylic acid. The corrosion inhibitor may be selectively attached to the surface of the metal contained in the metal-containing film, which is a film to be polished, thereby effectively suppressing excessive corrosion of the metal-containing film while maintaining a good polishing rate of the metal-containing film.

In an implementation, the corrosion inhibitor may include the azole-containing compound including triazole, tetrazole, benzotriazole, tolytriazole, aminotriazole, aminobenzimidazole, pyrazole, imidazole, aminotetrazole, or a combination thereof. For example, the corrosion inhibitor may be selected from 5-methyl-1H-benzotriazol, 2,2′-[[(5-methyl-1H-benzotriazol-1-yl)methyl]imino]bis-ethanol, 1,2,4-triazole, 1,2,3-triazole, 1,2,3-triazolo[4,5-b]pyridine, or a combination thereof. As the corrosion inhibitor, one type of material selected from the materials described above may be used alone or two or more types of materials may be mixed and used.

In an implementation, the corrosion inhibitor may be included in the slurry composition SC for polishing metal in an amount from about 0.001 wt. % to about 1 wt. %, such as from about 0.001 wt. % to about 0.5 wt. %, based on the total amount of the slurry composition SC for polishing metal. When the content of the corrosion inhibitor in the slurry composition SC is too small or too large, it may be difficult to maintain the good polishing rate of the metal-containing film to be polished.

### Catalyst

The catalyst may improve the oxidizing ability of the slurry composition SC and increase the removal rate of the metal-containing film to be polished.

In an implementation, the catalyst may include ferric nitrate, iron sulfate, and iron halides, iron-containing organic compounds, or a combination thereof. The iron halides may be selected from iron fluorides, iron chlorides, iron bromides, iron iodides, iron perchlorate, iron perbromates, and iron periodates, or a combination thereof. For example, the iron-containing organic compounds may be selected from iron acetates, iron acetylacetonates, iron citrates, iron gluconates, iron malonates, iron oxalates, iron phthalates, and iron succinates, or a combination thereof. The examples of catalyst are not limited thereto. As the catalyst, one type of material selected from the materials described above may be used alone or two or more types of materials may be mixed and used.

In an implementation, the catalyst may be included in the slurry composition SC in an amount from about 0.001% to about 0.1 wt. %, e.g., from about 0.001 wt. % to about 0.01 wt. %, based on the total amount of the slurry composition SC.

### Biocide

The biocide may prevent the slurry composition SC and/or the object to be polished from being contaminated with microorganisms. In an implementation, the biocide may include, but is not limited to, organo tin compounds, salicylanilide, formaldehyde, quaternary ammonium compounds, 2-bromo-2-nitropropane-1,3-diol (bronopol), 2,2-dibromo-3-nitrilopropionamide (DBNPA), isothiazolone, carbamate, quaternary phosphonium salts (e.g., tetrakis (hydroxymethyl)-phosphonium sulfate (THPS)), sodium chloride, sodium hypochlorite, trichloroisocyanuric acid, dichloroisocyanuric acid, calcium hypochlorite, lithium hypochlorite, chlorine dioxide, ozone, hydrogen peroxide, or combinations thereof.

When the slurry composition SC includes the biocide, the content of the biocide may be about 0.001 wt. % to about 10 wt. %, based on the total amount of the slurry composition SC. In an implementation, the content of the biocide may be from about 0.001 wt. % to about 5 wt. %, from about 0.001 wt. % to about 3 wt. %, or from about 0.001 wt. % to about 1 wt. %, based on the total amount of the slurry composition SC.

### Surfactant

The slurry composition SC may further include the surfactant as necessary. As the surfactant, an appropriate one of a nonionic surfactant, a cationic surfactant, an anionic surfactant, and an amphoteric surfactant may be selected and used.

Examples of the nonionic surfactant may include polyoxyethylene alkyl ethers, such as polyoxyethylene lauryl ether and polyoxyethylene stearyl ether; polyoxyethylene alkylphenyl ethers, such as polyoxyethylene octylphenyl ether and polyoxyethylene nonylphenyl ether; sorbitan higher fatty acid esters, such as sorbitan monolaurate, sorbitan monostearate, and sorbitan trioleate; polyoxyethylene sorbitan higher fatty acid esters, such polyoxyethylene sorbitan monolaurate; polyoxyethylene higher fatty acid esters, such as polyoxyethylene monolaurate and polyoxyethylene monostearate; glycerin higher fatty acid esters, such as oleic acid monoglyceride and stearic acid monoglyceride; and polyoxyalkylenes, such as polyoxyethylene, polyoxypropylene, and polyoxybutylene, and block copolymers thereof.

Examples of the cationic surfactant may include alkyl trimethylammonium chloride, dialkyl dimethyl ammonium chloride, benzalkonium chloride, and alkyl dimethylammonium ethosulfate.

Examples of the anionic surfactant may include carboxylates, such as sodium laurate, sodium oleate, N-acyl-N-methylglycine sodium salt, and sodium polyoxyethylene lauryl ether carboxylate; sulfonates, such as sodium dodecylbenzene sulfonate, dialkyl sulfosuccinic acid ester salt, and sodium dimethyl-5-sulfoisophthalate; sulfuric acid ester salts, such as sodium lauryl sulfate, sodium polyoxyethylene lauryl ether sulfate, and sodium polyoxyethylene nonylphenyl ether sulfate; and phosphoric acid ester salts, such as sodium polyoxyethylene lauryl phosphate and sodium polyoxyethylene nonylphenyl ether phosphate.

Examples of the amphoteric surfactant may include a carboxybetaine-type surfactant, aminocarboxylate, imidazolium betaine, lecithin, and alkylamine oxide.

The surfactant may be mixed with the slurry composition SC in a mixing ratio of about 0.001 wt. % to 0.5 wt. %.

### Polishing Inhibitor

The slurry composition SC may further include the polishing inhibitor as necessary. In an implementation, the polishing inhibitor may include a nitrogen-containing compound, e.g., an amine and a low molecular weight nitrogen-containing heterocyclic compound, such as benzotriazole, 1,2,3-triazole, and 1,2,4-triazole.

The polishing inhibitor may be mixed with the slurry composition SC in a mixing ratio of about 0.1 wt. % to 1 wt. % based on the total amount of the slurry composition SC.

### Leveling Agent

The slurry composition SC may further include the leveling agent for reducing unevenness of the surface to be polished as necessary.

In an implementation, the leveling agent may include ammonium chloride, ammonium lauryl sulfate, polyethylene glycol, triethanolamine polyoxyethylene alkyl ether sulfate, polyvinylpyrrolidone, polyacrolein, and the like.

The leveling agent may be mixed with the slurry composition SC in a mixing ratio of about 0.1 wt. % to 1 wt. % based on the total amount of the slurry composition SC.

In an implementation, the polishing pad 10 may be used to polish the metal material film. In another implementation, the polishing pad 10 may be used to polish the insulating material film. The polishing pad 10 may include the above-described abrasive particles, a resin, and/or an adhesive. The abrasive layer 12 may include a resin and an abrasive particle. The adhesive may be located between the abrasive layer 12 and the support layer 14 and/or between the support layer 14 and the platen 20 to bond the abrasive layer 12 to the support layer 14 and/or bond the support layer 14 to the platen 20. The support layer 14 may include the resin. In an implementation, the support layer 14 may include a non-woven felt in which the resin is formed in a sheet shape, but the present disclosure is not limited thereto.

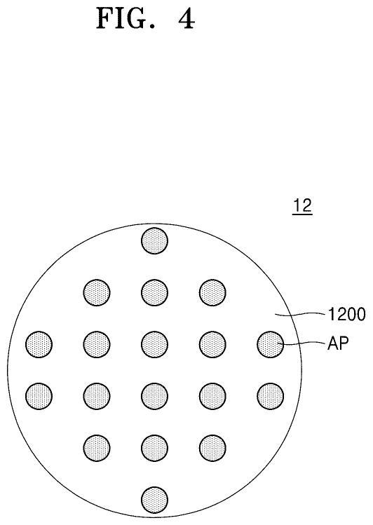

The resin may define the shape of the abrasive layer 12. The abrasive particles may be arranged inside the resin. In addition, the resin may define the shape of the support layer 14. The abrasive layer 12 may be described with reference to FIG. 4.

FIG. 4 is a plan view of an abrasive layer according to an implementation. FIG. 4 is a plan view of a top surface of the abrasive layer 12 in contact with the object to be polished.

Referring to FIG. 4, the abrasive layer 12 may include a base 1200 and abrasive particles AP disposed on a surface of the base 1200. The base 1200 defines an approximate shape of the abrasive layer 12 and may include a resin. For example, the base 1200 may have a cylindrical shape. In an implementation, the abrasive particles AP may be uniformly spaced apart from each other on the base 1200. In another implementation, the abrasive particles AP may be randomly spaced apart from each other on the base 1200. In an implementation, the abrasive particle AP may include the abrasive particle APa of FIG. 3.

### Resin

In an implementation, the resin may include at least one selected from the group consisting of polyethylene resin, polypropylene resin, polystyrene resin, polyvinylchloride resin, polyamide resin, acryl resin, polyurethane resin, polycarbonate resin, phenol resin, amino resin, epoxy resin, polyester resin, rubber, acrylonitrile butadiene styrene (ABS), and styrene acrylonitrile copolymers (SAN).

### Adhesive

In an implementation, the adhesive may include a pressure-sensitive adhesive (PSA) and/or a hot-melt adhesive (HMA). For example, the PSA may include an adhesive containing a polyacrylic component, an epoxy component, or a rubber component, or may include a double-sided PSA tape in which an adhesive material is applied to both surfaces of a substrate (e.g., a polyethylene terephthalate (PET) film or a felt), but is not limited thereto. For example, the HMA may include, but is not limited to, a cured reactive HMA.

Hereinafter, a semiconductor device manufacturing method using the slurry composition SC and/or the polishing pad 10 is described.

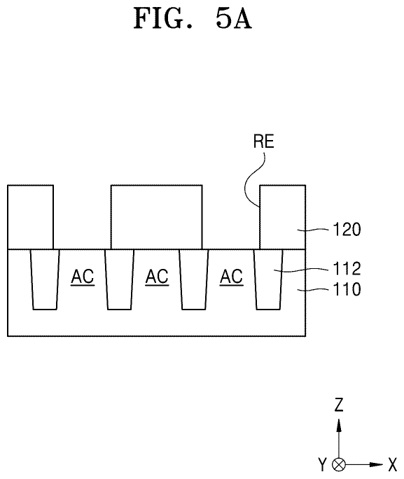

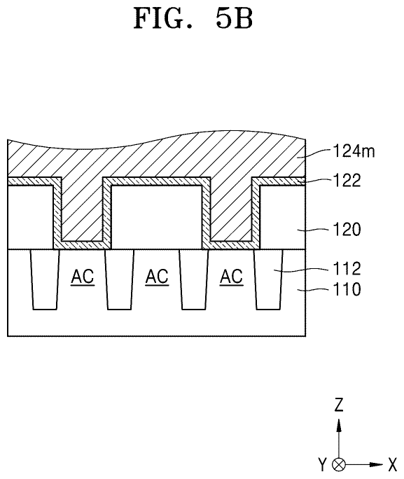

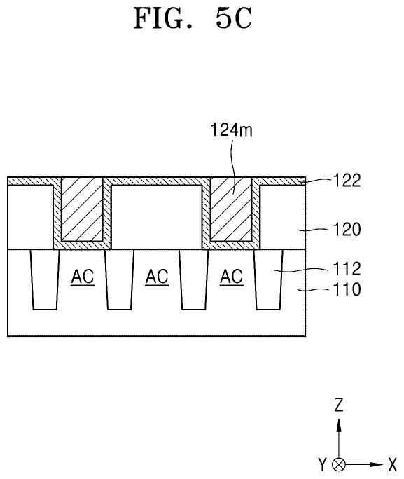

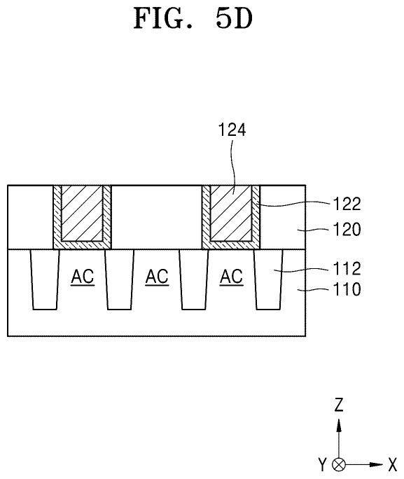

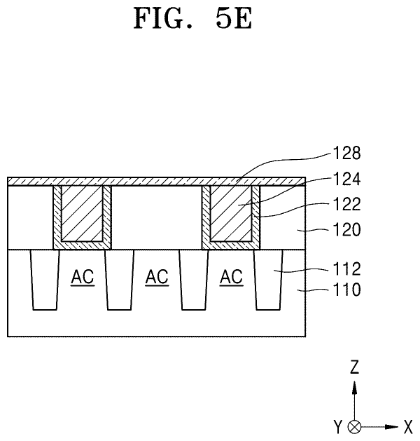

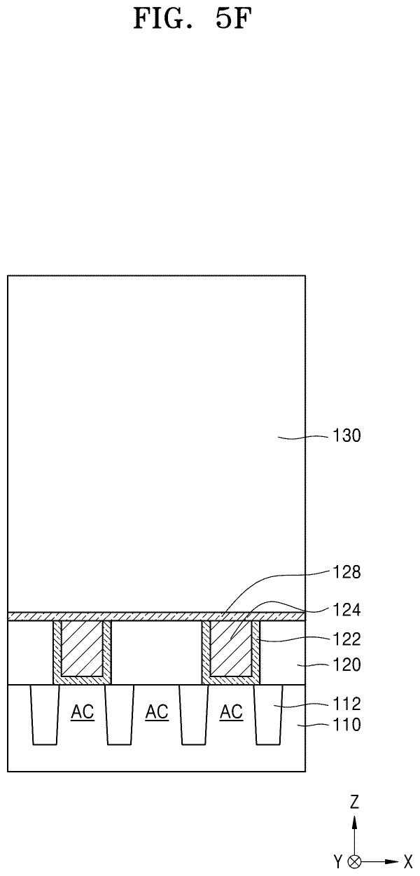

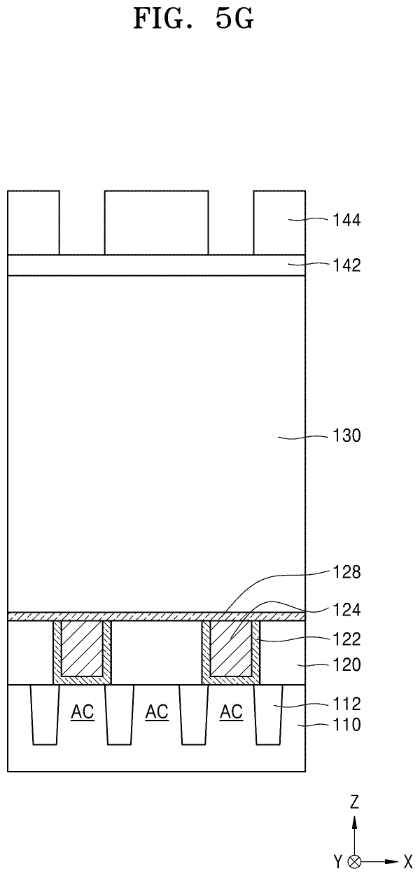

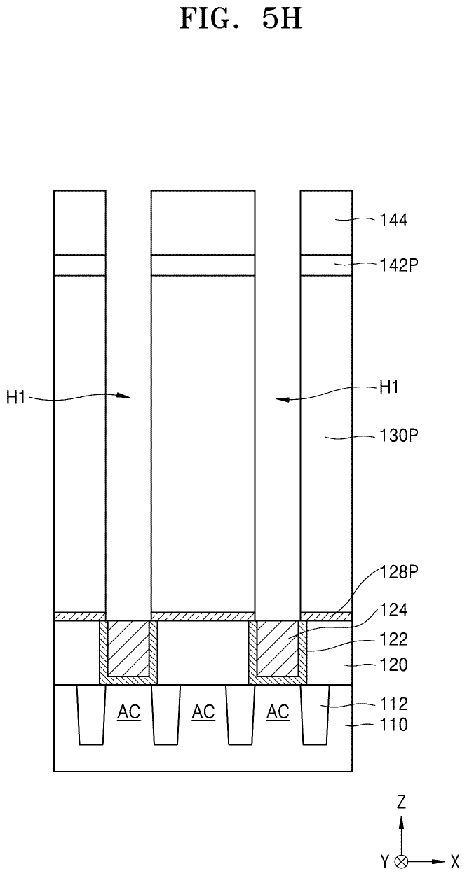

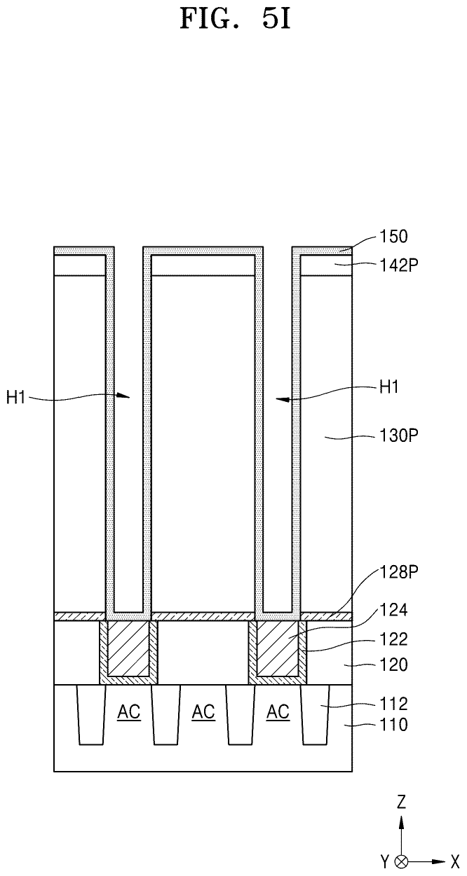

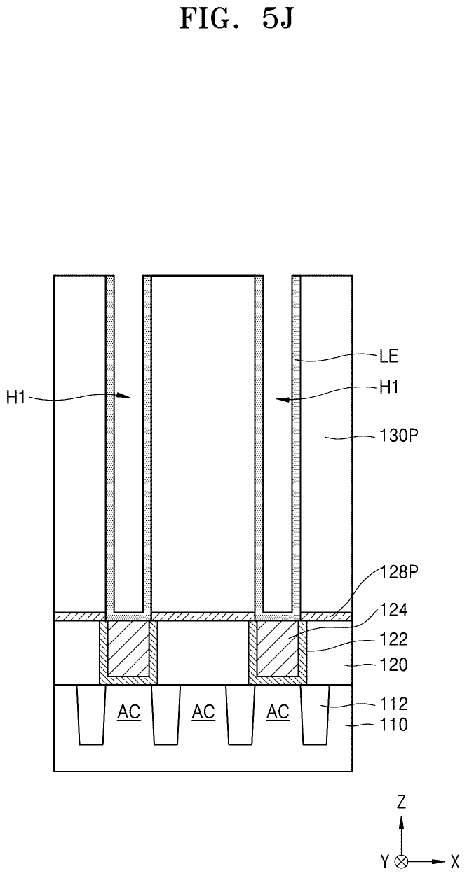

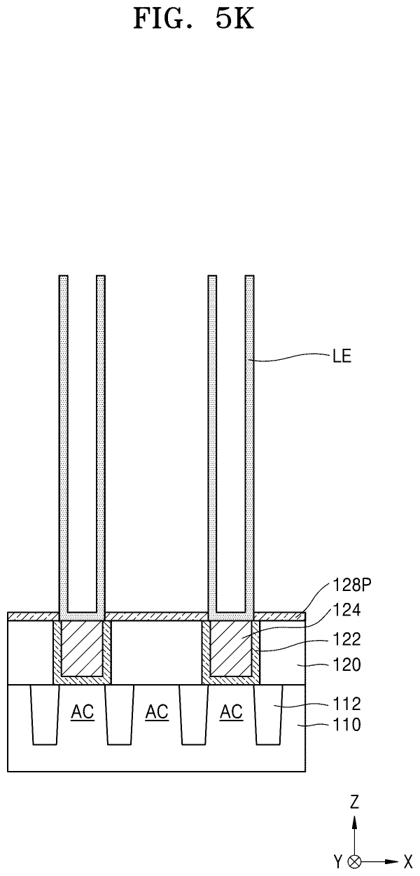

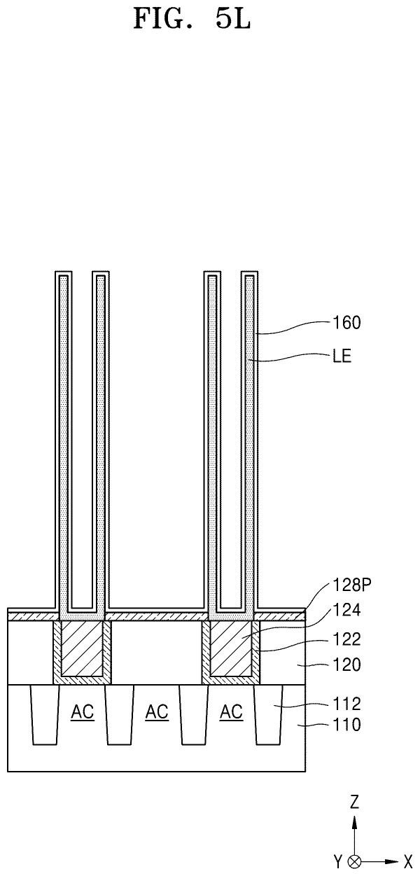

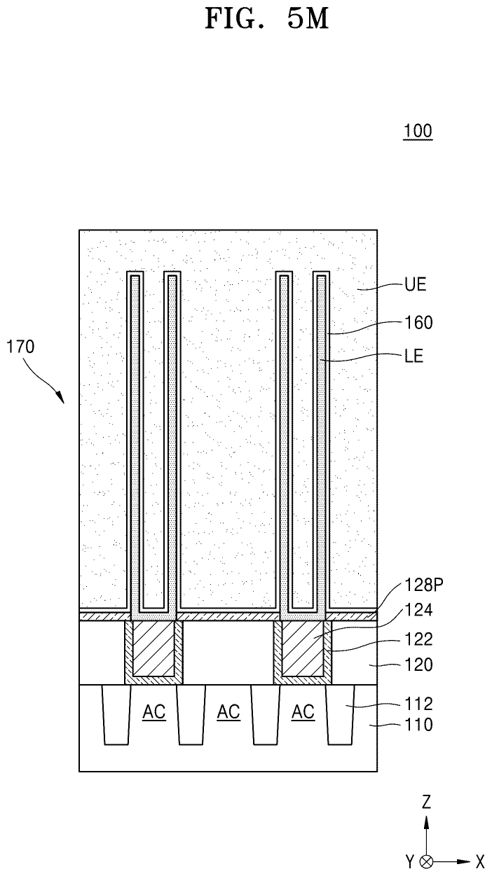

FIGS. 5A to 5M are cross-sectional views illustrating a semiconductor device manufacturing method, according to an implementation. FIGS. 5A to 5M are examples showing the process of polishing a metal material film using the slurry composition SC and/or the polishing pad 10.

Referring to FIG. 5A, on a substrate 110 including a plurality of active regions AC, an interlayer insulating film 120 patterned to at least partially expose the plurality of active regions AC may be formed. The interlayer insulating film 120 may include a recess RE that exposes the active region AC. The recess RE may include a contact hole or may be in the form of a trench. Although the recess RE is described as the contact hole, those skilled in the art may understand that the same present disclosure may be applied to the form of the trench.

The substrate 110 may include a semiconductor, such as Si or Ge, or a compound semiconductor, such as SiGe, SiC, GaAs, InAs, or InP. In an implementation, the substrate 110 may include at least one of a group III-V material and a group IV material. The group III-V material may include a binary, ternary, or quaternary compound including at least one group III atom and at least one group V atom. The group III-V material may include a compound including at least one atom of In, Ga and Al as the group III atom and at least one atom of As, P and Sb as the group V atom. For example, the group III-V material may be selected from InP, In_{z}Ga_{1-z}As (0≤z≤1), and Al_{z}Ga_{1-z}As (0≤z≤1). The binary compound may include, for example, any one of InP, GaAs, InAs, InSb, and GaSb. The ternary compound may include any one of InGaP, InGaAs, AlInAs, InGaSb, GaAsSb and GaAsP. The group IV material may include Si or Ge. However, the group III-V material and the group IV material that can be used in the integrated circuit device according to the present disclosure are not limited to those described above. In another implementation, the substrate 110 may have a silicon on insulator (SOI) structure. The substrate 110 may include a conductive region, e.g., an impurity-doped well, or an impurity-doped structure.

The plurality of active regions AC may be defined by a plurality of device isolation regions 112 formed in the substrate 110. The device isolation regions 112 may include a silicon oxide film, a silicon nitride film, a silicon oxynitride film, or a combination thereof. The interlayer insulating film 120 may include a silicon oxide film.

Referring to FIG. 5B, a barrier metal material layer 122 is formed in the recess RE and on the entire top surface of the interlayer insulating film 120. The barrier metal material layer 122 may be formed by atomic layer deposition (ALD), chemical vapor deposition (CVD), or physical vapor deposition (PVD). The barrier metal material layer 122 may include, for example, Ti and/or TiN.

In addition, a conductive material layer 124m may be formed on the entire top surface of the barrier metal material layer 122. The conductive material layer 124m may include doped polysilicon or a metal, such as tungsten (W), and may be formed by CVD.

Referring to FIG. 5C, the CMP may be performed on the conductive material layer 124m to confine the conductive material layer 124m to the inside of the recess RE. To this end, the slurry composition and/or the polishing pad as described above may be used, wherein the slurry composition and/or the polishing pad may include a phase-change material that changes phase in a processing temperature range of a CMP process. At this time, the barrier metal material layer 122 may be utilized as a polishing stop film to perform the CMP.

Referring to FIG. 5D, by performing the CMP on the exposed barrier metal material layer 122, the barrier metal material layer 122 may be defined in each contact hole and the complete node separation between the contact holes may be performed. To this end, the slurry composition and/or the polishing pad may be used as described above.

In the process of FIG. 5D, as in the process described with reference to FIG. 5C, the slurry composition and/or the polishing pad may include a phase-change material that changes phase in the processing temperature range of the CMP process.

FIGS. 5C and 5D illustrate that the two-step CMP is performed using each of the barrier metal material layer 122 and the interlayer insulating film 120 as the polishing stop film. However, in some implementations, only the interlayer insulating film 120 may be used as the polished stop film to perform the single-step CMP.

The plurality of conductive regions 124 may be connected to one terminal of a switching device, such as a field effect transistor formed on the substrate 110. The plurality of conductive regions 124 may include doped polysilicon, metal, conductive metal nitride, metal silicide, or a combination thereof, but are not limited to those described above.

Referring to FIG. 5E, an insulating layer 128 covering an interlayer insulating film 120 and the plurality of conductive regions 124 is formed. The insulating layer 128 may be used as an etch stop layer.

The insulating layer 128 may include an insulating material having an etching selectivity with respect to the interlayer insulating film 120 and a molding film 130 (see FIG. 5F) formed in a subsequent process. In an implementation, the insulating layer 128 may include silicon nitride, silicon oxynitride, or a combination thereof. In an implementation, the insulating layer 128 may be formed to a thickness of about 10 nm to about 60 nm, but is not limited thereto.

Referring to FIG. 5F, the molding film 130 is formed on the insulating layer 128. In an implementation, the molding film 130 may include an oxide film. For example, the molding film 130 may include an oxide film, such as boro phospho silicate glass (BPSG), phospho silicate glasses (PSG), undoped silicate glass (USG), spin on dielectric (SOD), or an oxide film formed by a high density plasma chemical vapor deposition (HDP CVD) process. To form the molding film 130, a thermal CVD process or a plasma CVD process may be used. In an implementation, the molding film 130 may be formed to a thickness of about 100 nm to about 2000 nm, but is not limited thereto.

In an implementation, the molding film 130 may include a support film. The support film may include a material having an etching selectivity with respect to the molding film 130, and may have a thickness of about 5 nm to about 300 nm. The support film may include a material having a relatively low etching rate with respect to an etching atmosphere used when removing the molding film 130 in a subsequent process, for example, an etchant including ammonium fluoride (NH₄F), hydrofluoric acid (HF), and water. In an implementation, the support film may include silicon nitride, silicon carbonitride, tantalum oxide, titanium oxide, or a combination thereof, but the materials constituting the support film are not limited to those described above.

Referring to FIG. 5G, a sacrificial film 142 and a mask pattern 144 are sequentially formed on the molding film 130. The sacrificial film 142 may include an oxide film, such as an oxide film formed by a BPSG, PSG, USG, SOD, or HDP CVD process. The sacrificial film 142 may have a thickness of about 50 nm to about 200 nm. The sacrificial film 142 may protect the support film included in the molding film 130.

The mask pattern 144 may include an oxide film, a nitride film, a polysilicon film, a photoresist film, or a combination thereof. A region in which the lower electrode of the capacitor is to be formed may be defined by the mask pattern 144.

Referring to FIG. 5H, the sacrificial film 142 and the molding film 130 are dry-etched by using the mask pattern 144 as an etching mask and using the insulating layer 128 as an etch stop layer, and a sacrificial pattern 142P and a molding pattern 130P defining a plurality of holes H1 are formed.

In this case, the insulating layer 128 may also be etched by transient etching to form the insulating pattern 128P exposing the plurality of conductive regions 124.

Referring to FIG. 5I, after the mask pattern 144 is removed from the resultant of FIG. 5H, a conductive film 150 for forming the lower electrode is formed to cover the inner sidewall of each of the plurality of holes H1, the exposed surface of the insulating pattern 128P, the surfaces of the plurality of conductive regions 124 respectively exposed in the plurality of holes H1, and the exposed surface of the sacrificial pattern 142P.

The conductive film 150 for forming the lower electrode may be conformally formed on the sidewalls of the plurality of holes H1 so that the partial internal space of each of the plurality of holes H1 remains.

In an implementation, the conductive film 150 for forming the lower electrode may include a doped semiconductor, a conductive metal nitride, a metal, a metal silicide, a conductive oxide, or a combination thereof. For example, the conductive film 150 for forming the lower electrode may include TIN, TiAlN, TaN, TaAlN, W, WN, Ru, RuO₂, SrRuO₃, Ir, IrO₂, Pt, PtO, SRO (SrRuO₃), BSRO ((Ba,Sr)RuO₃), CRO (CaRuO₃), LSCO ((La,Sr)CoO₃), or a combination thereof, but the material constituting the conductive film 150 is not limited thereto.

To form the conductive film 150 for forming the lower electrode, the CVD, metal organic CVD (MOCVD), or ALD process may be used. The conductive film 150 for forming the lower electrode may be formed to have a thickness of about 1 nm to about 100 nm, but is not limited thereto. Thereafter, although not shown in FIG. 5I, a sacrificial film may be further formed to fill the inside of the recess defined by the conductive film 150 for forming the lower electrode. The sacrificial film may cover the top surface of the conductive film 150 for forming the lower electrode.

Referring to FIG. 5J, the upper portion of the conductive film 150 for forming the lower electrode is partially removed to separate the conductive film 150 into a plurality of lower electrodes LE.

To form the plurality of lower electrodes LE, the upper portion of the conductive film 150 for forming the lower electrode and the sacrificial pattern 142P (see FIG. 5I) may be partially removed using the etchback or CMP process so that the top surface of the molding pattern 130P is exposed. The plurality of lower electrodes LE may pass through the insulating pattern 128P and may be connected to the conductive regions 124, respectively.

Referring to FIG. 5K, the molding pattern 130P is removed to expose the outer wall surfaces of the plurality of cylindrical lower electrodes LE. The molding pattern 130P may be removed by a lift-off process using an etchant.

Referring to FIG. 5L, a dielectric film 160 is formed on the plurality of lower electrodes LE. The dielectric film 160 may be formed to conformally cover the exposed surfaces of the plurality of lower electrodes LE. The dielectric film 160 may be formed by an ALD process.

The dielectric film 160 may include an oxide, a metal oxide, a nitride, or a combination thereof. In an implementation, the dielectric film 160 may include a ZrO₂ film. For example, the dielectric film 160 may include a single layer of ZrO₂ film or may include multiple layers of a combination of at least one ZrO₂ film and at least one Al₂O₃film.

In an implementation, the dielectric film 160 may have a thickness of about 5 nm to about 15 nm, but is not limited thereto.

Referring to FIG. 5M, an upper electrode UE is formed on the dielectric film 160. A capacitor 170 may be configured by the lower electrode LE, the dielectric film 160, and the upper electrode UE.

The upper electrode UE may include a doped semiconductor, a conductive metal nitride, a metal, a metal silicide, a conductive oxide, or a combination thereof. For example, the upper electrode UE may include TIN, TiAlN, TaN, TaAlN, W, WN, Ru, RuO₂, SrRuO₃, Ir, IrO₂, Pt, PtO, SRO (SrRuO₃), BSRO((Ba,Sr)RuO₃), CRO(CaRuO₃), LSCO((La,Sr)CoO₃), or a combination thereof, but the material constituting the upper electrode UE is not limited thereto. To form the upper electrode UE, the CVD, MOCVD, PVD, or ALD process may be used.

Although the semiconductor device manufacturing method including forming the dielectric film 160 covering the surface of the cylindrical lower electrode LE has been described above with reference to FIGS. 5A to 5M, the present disclosure is not limited thereto. For example, instead of the cylindrical lower electrode LE, a pillar-shaped lower electrode having no internal space may be formed, and the dielectric film 160 may be formed on the pillar-shaped lower electrode.

According to the semiconductor device manufacturing method according to some implementations described with reference to FIGS. 5A to 5M, the CMP is performed by using the slurry composition and/or the polishing pad, according to the present disclosure, to form the barrier metal material layer 122 and the conductive region 124. However, those skilled in the art may understand that the CMP is performed using the slurry composition and/or the polishing pad according to the present disclosure for manufacturing other semiconductor devices.

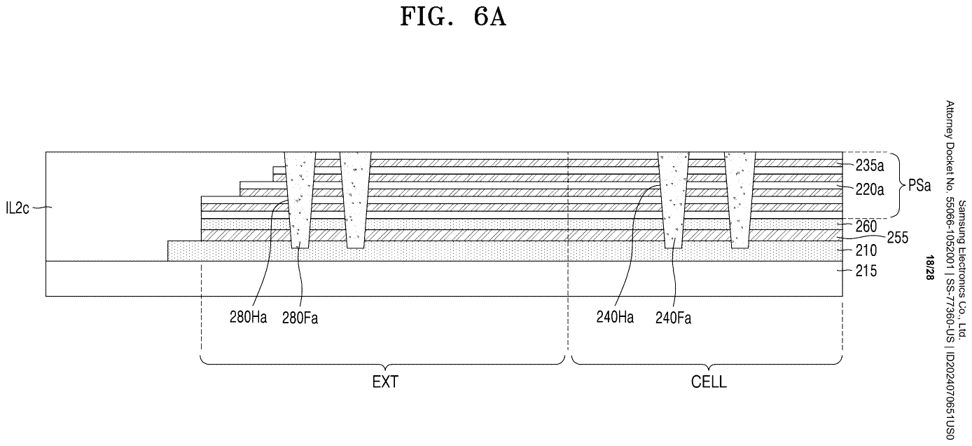

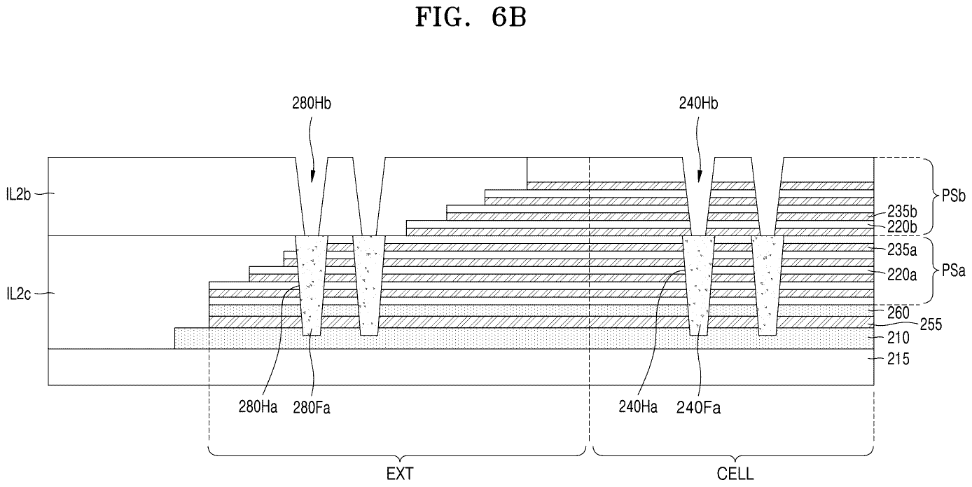

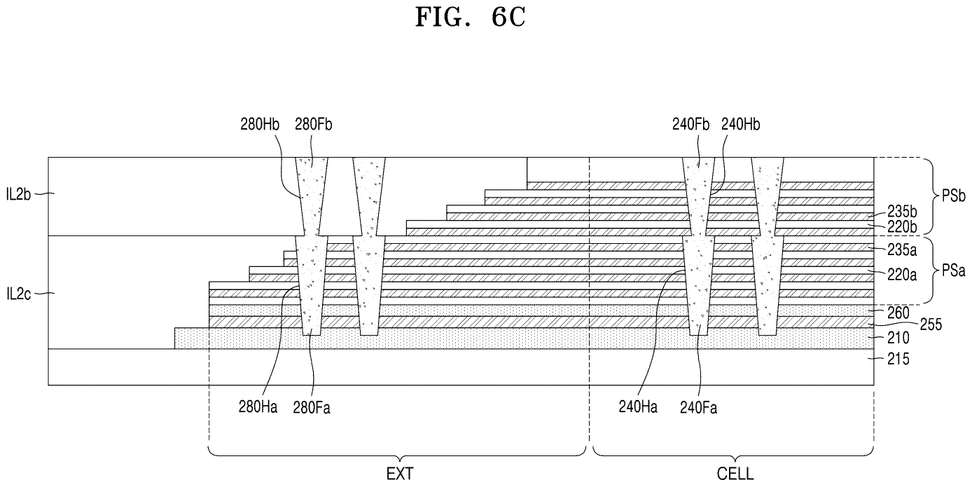

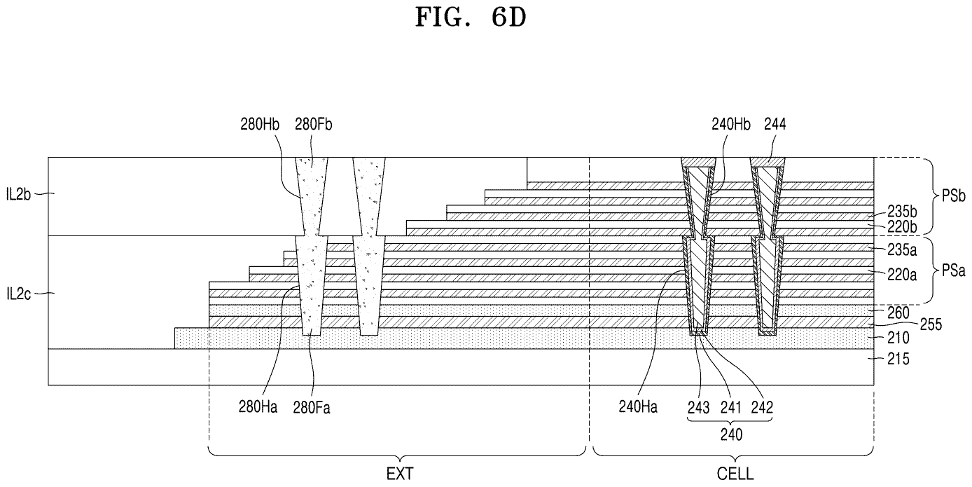

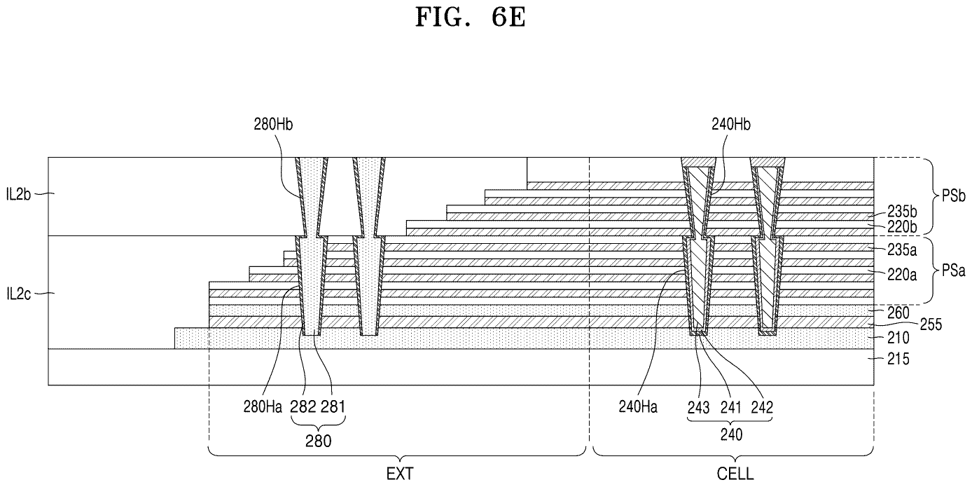

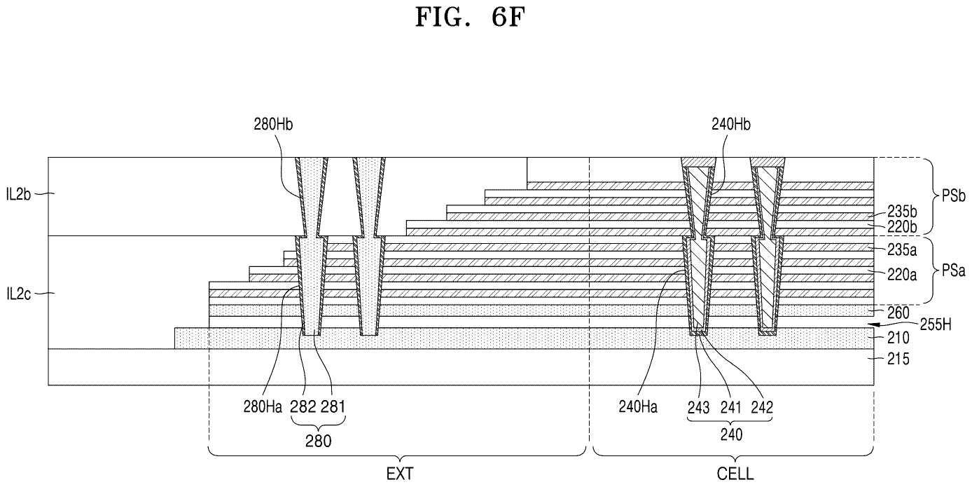

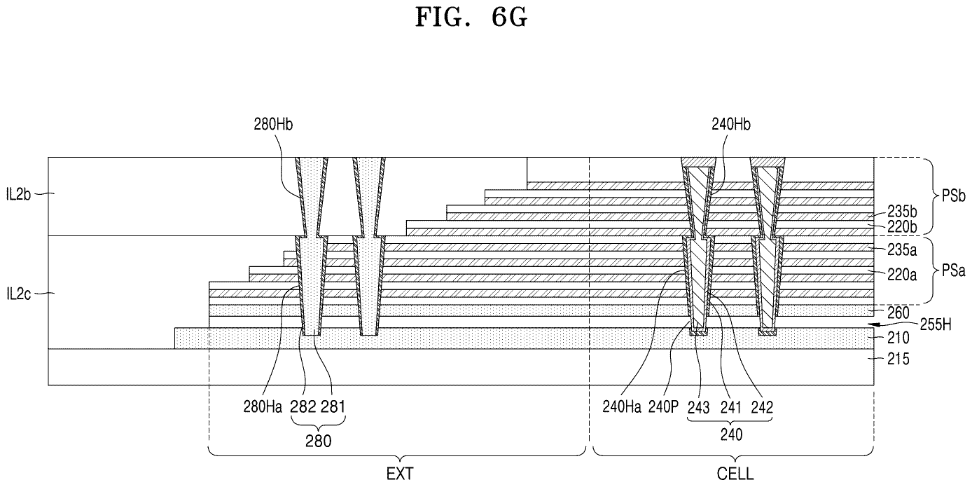

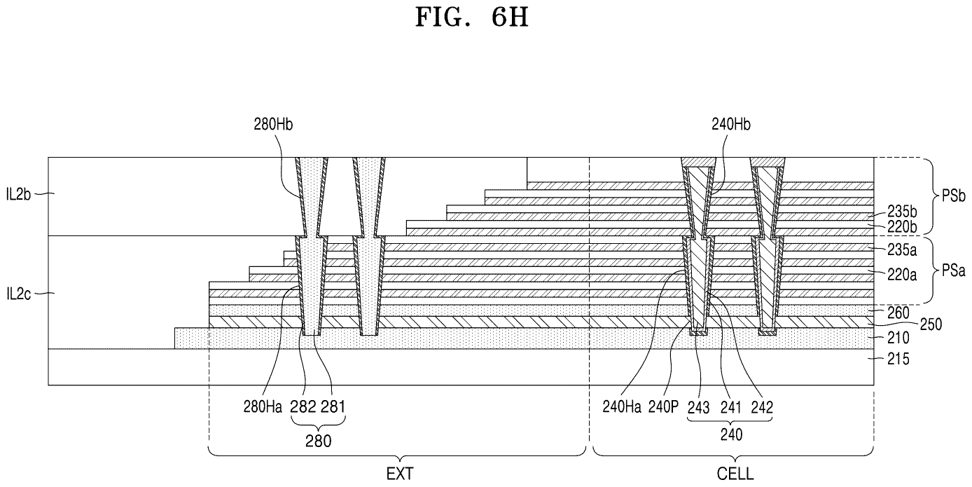

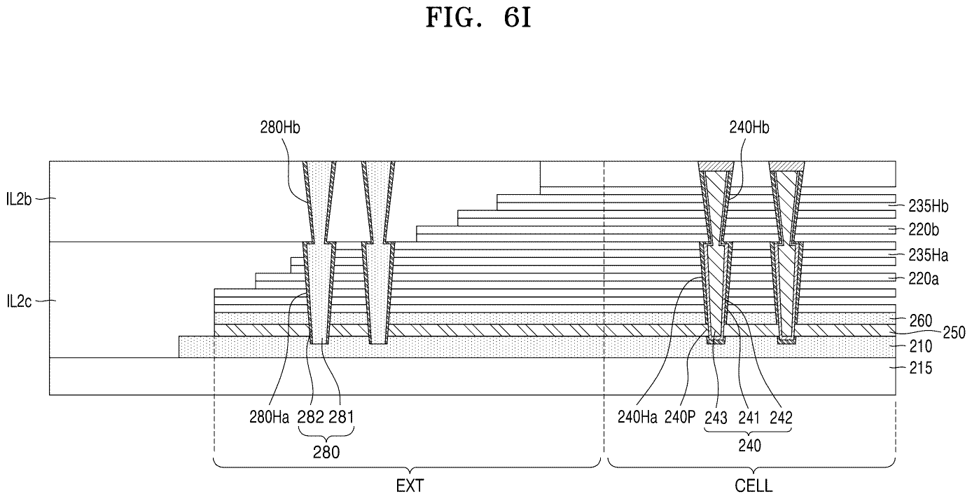

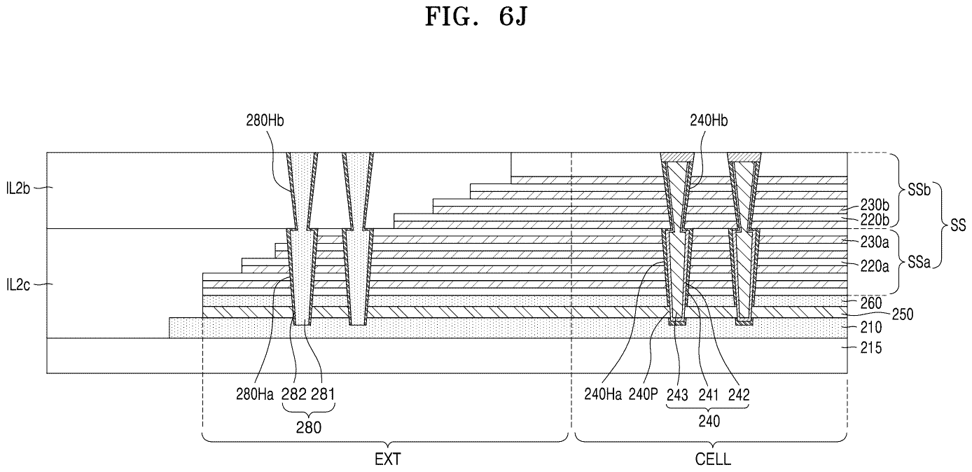

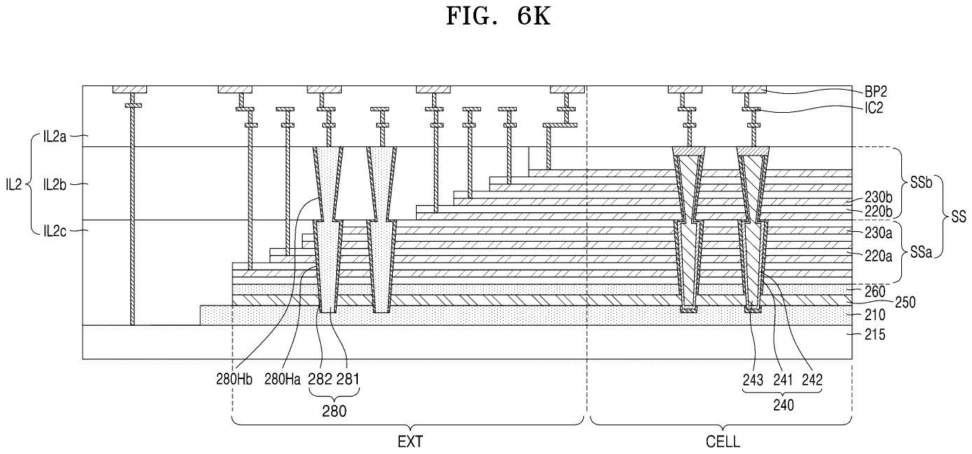

FIGS. 6A to 6K are cross-sectional views illustrating a semiconductor device manufacturing method, according to an implementation. FIGS. 6A to 6K are examples showing the process of polishing the insulating material film using the slurry composition and/or the polishing pad of the present disclosure.

Referring to FIG. 6A, a substrate 215 may be provided first. The substrate 215 may include, e.g., a semiconductor material, such as a group IV semiconductor material, a group III-V semiconductor material, or a group II-VI semiconductor material. A common source line layer 210 may be formed on the substrate 215. A first portion PSa of a preliminary stacking structure may be formed on the common source line layer 210. The first portion PSa of the preliminary stacking structure may be formed by alternately forming a plurality of first interlayer insulating layers 220a and a plurality of first sacrificial layers 235a on the common source line layer 210. Each of the first sacrificial layers 235a may include a material having an etching selectivity with respect to each of the first interlayer insulating layers 220a. For example, when the first interlayer insulating layer 220a includes silicon oxide, the first sacrificial layer 235a may include silicon nitride.

In an implementation, a lower sacrificial layer 255 may be further formed between the common source line layer 210 and the first portion PSa of the preliminary stacking structure. In an implementation, a lower support layer 260 may be further formed between the lower sacrificial layer 255 and the first portion PSa of the preliminary stacking structure. The lower sacrificial layer 255 may include a material having an etching selectivity with respect to the common source line layer 210 and the lower support layer 260. For example, when the common source line layer 210 and the lower support layer 260 include polysilicon, the lower sacrificial layer 255 may include silicon nitride.

The preliminary stacking structure may be patterned such that a step region EXT of the first portion PSa of the preliminary stacking structure has a step shape. Next, a first portion IL2c of an insulating structure may be formed on the substrate 215 and the first portion PSa of the preliminary stacking structure. Next, a first channel hole 240Ha penetrating a cell region CELL of the first portion PSa of the preliminary stacking structure and a first dummy channel hole 280Ha penetrating a step region EXT of the first portion PSa of the preliminary stacked structure may be formed. The first dummy channel hole 280Ha may further penetrate the first portion IL2c of the insulating structure. The first channel hole 240Ha and the first dummy channel hole 280Ha may further penetrate the lower support layer 260 and the lower sacrificial layer 255.

Next, the first channel hole 240Ha and the first dummy channel hole 280Ha are filled with a first filling layer 240Fa and a first dummy filling layer 280Fa, respectively. The first filling layer 240Fa and the first dummy filling layer 280Fa may include polysilicon in an implementation.

To form the first filling layer 240Fa and the first dummy filling layer 280Fa, polysilicon may be formed inside the first channel hole 240Ha and the first dummy channel hole 280Ha as well as on the uppermost first interlayer insulating layer 220a. Thereafter, by performing the CMP using the top surface of the first interlayer insulating layer 220a as the polishing stop film, polysilicon is confined inside the first channel hole 240Ha and the first dummy channel hole 280Ha. The polysilicon may be removed with high reliability by using the slurry composition and/or the polishing pad according to the present disclosure when performing the CMP.

Referring to FIG. 6B, a second portion PSb of the preliminary stacking structure may be formed on the first portion PSa of the preliminary stacking structure. The second portion PSb of the preliminary stacking structure may be formed by alternately forming a plurality of second interlayer insulating layers 220b and a plurality of second sacrificial layers 235b on the first portion PSa of the preliminary stacked structure. Each second sacrificial layer 235b may include a material having an etching selectivity with respect to each second interlayer insulating layer 220b. For example, when the second interlayer insulating layer 220b includes silicon oxide, the second sacrificial layer 235b may include silicon nitride.

Next, the second portion PSb of the preliminary stacking structure may be patterned such that the step region EXT of the second portion PSb of the preliminary stacked structure has a step shape. Next, a second portion IL2b of the insulating structure may be formed on the first portion IL2c of the insulating structure and the first portion PSa and the second portion PSb of the preliminary stacking structure. Next, a second channel hole 240Hb that penetrates the second portion PSb of the preliminary stacking structure to expose the first filling layer 240Fa and a second dummy channel hole 280Hb that penetrates the second portion IL2b of the insulating structure to expose the first dummy filling layer 280Fa may be formed.

Referring to FIG. 6C, the second channel hole 240Hb and the second dummy channel hole 280Hb may be filled with a second filling layer 240Fb and a second dummy filling layer 280Fb, respectively. In an implementation, the second filling layer 240Fb and the second dummy filling layer 280Fb may include polysilicon.

The polysilicon may be formed inside the second channel hole 240Hb and the second dummy channel hole 280Hb as well as on the uppermost layer of the second portion PSb to form the second filling layer 240Fb and the second dummy filling layer 280Fb. Then, by performing the CMP using the uppermost layer as the polishing stop film, the polysilicon may be confined inside the second channel hole 240Hb and the second dummy channel hole 280Hb. The polysilicon may be removed with high reliability by using the slurry composition and/or the polishing pad according to the present disclosure when performing the CMP.

Referring to FIGS. 6C and 6D, the first filling layer 240Fa and the second filling layer 240Fb may be removed from the first channel hole 240Ha and the second channel hole 240Hb, respectively. A mask that covers the second dummy filling layer 280Fb and exposes the second filling layer 240Fb may be formed before removing the first filling layer 240Fa and the second filling layer 240Fb to prevent the first dummy filling layer 280Fa and the second dummy filling layer 280Fb from being removed. The mask may be removed after removing the first filling layer 240Fa and the second filling layer 240Fb.

Next, a channel structure 240 may be formed in the first channel hole 240Ha and the second channel hole 240Hb. A gate insulating layer 241 may be formed on the first channel hole 240Ha and the second channel hole 240Hb. For example, the gate insulating layer 241 may be formed by sequentially forming a blocking insulating layer, a charge storage layer, and a tunneling insulating layer on the first channel hole 240Ha and the second channel hole 240Hb. A channel layer 242 may be formed on the gate insulating layer 241. A buried insulating layer 243 may be formed on the channel layer 242. The buried insulating layer 243 may form the channel structure 240 by filling the first channel hole 240Ha and the second channel hole 240Hb together with the gate insulating layer 241 and the channel layer 242. Next, portions of the gate insulating layer 241, the channel layer 242, and the buried insulating layer 243 in the end of the second channel hole 240Hb may be removed, and a channel pad 244 may be formed in the end of the second channel hole 240Hb.

Referring to FIGS. 6D and 6E, the first dummy filling layer 280Fa and the second dummy filling layer 280Fb may be removed from the first dummy channel hole 280Ha and the second dummy channel hole 280Hb, respectively. In an implementation, to prevent the channel structure 240 from being removed, a mask covering the channel structure 240 and exposing the second dummy filling layer 280Fb may be formed before removing the first dummy filling layer 280Fa and the second dummy filling layers 280Fb. The mask may be removed after removing the first dummy filling layer 280Fa and the second dummy filling layer 280Fb.

Next, a dummy channel structure 280 may be formed in the first dummy channel hole 280Ha and the second dummy channel hole 280Hb. First, an insulating layer 282 may be formed on sidewalls of the first dummy channel hole 280Ha and the second dummy channel hole 280Hb. For example, the insulating layer 282 may be formed on a top surface of the second portion IL2b of the insulating structure, a sidewall of the second dummy channel hole 280Hb, and a sidewall and a bottom surface of the first dummy channel hole 280Ha, and the insulating layer 282 on the top surface of the second portion IL2b and the bottom surface of the first dummy channel hole 280Ha may be removed by anisotropically etching the insulating layer 282. Next, a conductive layer 281 may be formed on the insulating layer 282. The conductive layer 281 may be formed to fill the first dummy channel hole 280Ha and the second dummy channel hole 280Hb, together with the insulating layer 282.

Referring to FIGS. 6E and 6F, a space 255H may be formed between the common source line layer 210 and the lower support layer 260 by removing the lower sacrificial layer 255. The gate insulating layer 241 of the channel structure 240 and the insulating layer 282 of the dummy channel structure 280 may be exposed to the space 255H. To remove the lower sacrificial layer 255, a word line cut that penetrates first portion PSa and the second portion PSb of the preliminary stacking structures and the lower support layer 260 and exposes the lower sacrificial layer 255, which is not illustrated with reference to FIGS. 6E and 6F, may be formed before removing the lower sacrificial layer 255. The etchant may reach and etch the lower sacrificial layer 255 through the word line cut.

Referring to FIGS. 6F and 6G, an opening 240P passing through the gate insulating layer 241 may be formed by removing a portion of the gate insulating layer 241 of the channel structure 240 exposed to the space 255H. The channel layer 242 may be exposed to the space 255H through the opening 240P. In an implementation, the thickness of the insulating layer 282 of the dummy channel structure 280 may be sufficiently large that the conductive layer 281 is not exposed to the space 255H even when the insulating layer 282 of the dummy channel structure 280 is exposed to the etchant for removing a portion of the gate insulating layer 241 of the channel structure 240. In another implementation, the conductive layer 281 may be exposed to the space 255H by exposing the insulating layer 282 of the dummy channel structure 280 to the etchant for removing a portion of the gate insulating layer 241 of the channel structure 240 and etching the exposed portion of the insulating layer 282.

Referring to FIGS. 6G and 6H, a lower conductive layer 250 may be formed in a space 255H. The lower conductive layer 250 may be in contact with the channel layer 242 through the opening 240P. In an implementation, the lower conductive layer 250 may not be in contact with the conductive layer 281. Unlike shown in FIG. 6H, in another implementation, the lower conductive layer 250 may pass through the insulating layer 282 to be in contact with the conductive layer 281.

Referring to FIGS. 6H and 6I, a plurality of spaces 235Ha and 235Hb between the plurality of interlayer insulating layers 220a and 220b may be formed by removing the plurality of sacrificial layers 235a and 235b.

Referring to FIGS. 6I and 6J, a plurality of gate layers 230a and 230b may be formed in the plurality of spaces 235Ha and 235Hb between the plurality of interlayer insulating layers 220a and 220b. Thus, a stacking structure SS including a first portion SSa including the first interlayer insulating layer 220a and the first gate layer 230a alternately stacked on the common source line layer 210 and a second portion SSb including the second interlayer insulating layer 220b and the second gate layer 230b alternately stacked on the first portion SSa may be formed.

Referring to FIG. 6K, a third portion IL2a of an insulating structure IL2, an interconnect structure IC2, and a plurality of bonding pads BP2 may be formed. Thus, the insulating structure IL2 including the first portion IL2c, the second portion IL2b, and the third portion IL2a may be completed.

As used herein, the term “and/or” as used herein refers to and encompasses any and all possible combinations of one or more of the associated listed terms. For example, the term “A and/or B” means that either option A, option B, or both options A and B are possible, where A and B may be singular or plural.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vii) at least one of A, at least one of B and at least one of C are possible, where A, B and C may be singular or plural.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A slurry composition comprising:
an abrasive particle comprising a core comprising a phase-change material that exhibits a phase change within a processing temperature range of a chemical mechanical polishing (CMP) process; and
a shell surrounding the core, the shell comprising a material that is different from the phase-change material of the core.

2. The slurry composition of claim 1, wherein the phase-change material comprises a material that changes phase within a temperature range of about 30° C. to about 80° C.

3. The slurry composition of claim 1, wherein the phase-change material is meltable within the processing temperature range.

4. The slurry composition of claim 1, wherein a concentration of the abrasive particle in the slurry composition is between about 0.05 wt. % and about 30 wt. % of a total weight of the slurry composition.

5. The slurry composition of claim 1, wherein the abrasive particle has a size of about 5 nm to about 200 nm.

6. The slurry composition of claim 1, wherein the core comprises at least one of lauric acid, palmitic acid, stearic acid, or myristic acid.

7. The slurry composition of claim 1, wherein the shell comprises at least one of silica, alumina, ceria, titania, zirconia, magnesia, germania, or mangania.

8. The slurry composition of claim 1, wherein the shell comprises a first shell surrounding the core and a second shell surrounding the first shell, and wherein the first shell and the second shell comprise different materials.

9. The slurry composition of claim 1, comprising a polishing accelerator, a pH adjuster, an oxidizing agent, and water.

10. The slurry composition of claim 1, comprising a corrosion inhibitor and/or a catalyst,
wherein the corrosion inhibitor comprises an azole-containing compound and/or a water-soluble polymer that includes an anionic carboxylic acid, and wherein the catalyst comprises an iron-containing compound.

11. A polishing pad, comprising:
a base; and
an abrasive particle on a surface of the base, the abrasive particle comprising
a core comprising a phase-change material that exhibits a phase change within a processing temperature range of a chemical mechanical polishing (CMP) process, and
a shell surrounding the core, the shell comprising a material that is different from the phase-change material of the core.

12. The polishing pad of claim 11, wherein the phase-change material comprises a material that changes phase within a range of about 30° C. to about 80° C.

13. The polishing pad of claim 11, wherein the base comprises at least one of polyethylene resin, polypropylene resin, polystyrene resin, polyvinylchloride resin, polyamide resin, acryl resin, polyurethane resin, polycarbonate resin, phenol resin, amino resin, epoxy resin, polyester resin, rubber, acrylonitrile butadiene styrene (ABS), or styrene-acrylonitrile copolymers (SAN).

14. The polishing pad of claim 11, comprising
a support layer, and
an abrasive layer on the support layer, the abrasive layer comprising the abrasive particle.

15. The polishing pad of claim 14, wherein a concentration of the abrasive particle is between about 0.05 wt. % and about 30 wt. % of a total weight of the abrasive layer.

16. The polishing pad of claim 11, wherein the polishing pad has a three-dimensional structure.

17. A semiconductor device manufacturing method, comprising:
forming an object to be polished on a substrate; and
performing a chemical mechanical polishing (CMP) process using a slurry composition and a polishing pad to polish the object,
wherein at least one of the slurry composition and the polishing pad comprises an abrasive particle, the abrasive particle comprising
a core comprising a phase-change material that exhibits a phase change in a temperature range of about 30° C. to about 80° C., and
a shell surrounding the core, the shell comprising a material that is different from the phase-change material of the core.

18. The semiconductor device manufacturing method of claim 17, wherein the slurry composition comprises a polishing accelerator, a pH adjuster, an oxidizing agent, and water, and
wherein the polishing pad comprises a resin.

19. The semiconductor device manufacturing method of claim 17, wherein the abrasive particle has a size of about 5 nm to about 200 nm.

20. The semiconductor device manufacturing method of claim 17, wherein the object comprises a metal material film.

21. The semiconductor device manufacturing method of claim 17, wherein the core comprises at least one of lauric acid, palmitic acid, stearic acid, or myristic acid, and
wherein the shell comprises at least one of silica, alumina, ceria, titania, zirconia, magnesia, germania, or mangania.

22. The semiconductor device manufacturing method of claim 17, wherein the shell includes a single layer.

23. The semiconductor device manufacturing method of claim 17, wherein the shell comprises a first shell surrounding the core and a second shell surrounding the first shell, and
wherein thermal conductivity of the first shell is greater than thermal conductivity of the second shell.

24. The semiconductor device manufacturing method of claim 17, wherein the slurry composition comprises a corrosion inhibitor and/or a catalyst,
wherein the corrosion inhibitor comprises an azole-containing compound and/or a water-soluble polymer that includes an anionic carboxylic acid, and
wherein the catalyst comprises an iron-containing compound.

25. The semiconductor device manufacturing method of claim 17, wherein each of the slurry composition and the polishing pad comprises the abrasive particle.

26. The semiconductor device manufacturing method of claim 17, wherein the object comprises an insulating material film.
